(19) United States
(12) Patent Application Publication
(10) Pub. No.: US 2026/0020249 A1
(43) Pub. Date: Jan. 15, 2026

(54) CROSSBAR CIRCUITS UTILIZING OVONIC THRESHOLD SWITCHING (OTS) MEMORY DEVICES

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/768,552

(22) Filed: Jul. 10, 2024

(51) Int. Cl. H10B 63/00; G11C 5/06; H10N 70/00

(52) U.S. Cl. CPC H10B 63/24; G11C 5/063; H10N 70/021; H10N 70/841; H10N 70/8822; H10N 70/8825; H10N 70/8828

(57) ABSTRACT

The present disclosure provides memory devices exhibiting Ovonic threshold switching (OTS) switching characteristics and crossbar circuits incorporating the memory devices. In some embodiments, an OTS memory device may include a first electrode, a first interface layer fabricated on the first electrode, a chalcogenide switching layer fabricated on the first interface layer, a second interface layer, and a second electrode. The chalcogenide switching layer comprises a chalcogenide. The first interface layer and the second interface layer may include a dielectric material that does not react with the chalcogenide and the electrode materials in the first electrode and the second electrode. The OTS memory device may function as both a switch and a non-volatile memory cell.

### TECHNICAL FIELD

The implementations of the disclosure relate generally to electronic devices and, more specifically, to crossbar circuits utilizing ovonic threshold switching (OTS) memory devices.

### BACKGROUND

A crossbar circuit may refer to a circuit structure with interconnecting electrically conductive lines sandwiching a memory element, such as a resistive switching material, at their intersections. The resistive switching material may include, for example, a memristor (also referred to as resistive random-access memory (RRAM or ReRAM)). Crossbar circuits may be used to implement in-memory computing applications, non-volatile solid-state memory, image processing applications, neural networks, etc.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a memory device is provided. The memory device includes a first electrode, a first interface layer fabricated on the first electrode, a chalcogenide switching layer fabricated on the first interface layer, and a second electrode fabricated on the chalcogenide switching layer. The chalcogenide switching layer includes at least one chalcogenide.

In some embodiments, the chalcogenide is a compound including at least one of sulfur (S), selenium (Se), or tellurium (Te).

In some embodiments, the first interface layer includes a first dielectric material that does not react with the chalcogenide and the first electrode.

In some embodiments, the first dielectric material includes at least one of Al₂O₃, Y₂O₃, or MgO.

In some embodiments, the first interface layer includes a discontinuous film of the first dielectric material. In such embodiments, at least a portion of the chalcogenide switching layer is deposited on the first electrode.

In some embodiments, the memory device further includes a second interface layer positioned between the chalcogenide switching layer and the second electrode. The second interface layer includes a second dielectric material that does not react with the chalcogenide and the second electrode.

In some embodiments, the second interface layer and the first interface layer are of different thicknesses.

In some embodiments, the second interface layer and the first interface layer include different materials.

In some embodiments, the first electrode and the second electrode compromise at least one of tungsten, molybdenum, ruthenium, titanium nitride, tantalum nitride, tungsten nitride, platinum, palladium, or iridium.

According to one or more aspects of the present disclosure, methods for fabricating a memory device are provided. The methods include fabricating a first electrode, fabricating a first interface layer fabricated on the first electrode, fabricating a chalcogenide switching layer fabricated on the first interface layer, and fabricating a second electrode on the chalcogenide switching layer. The chalcogenide switching layer includes at least one chalcogenide.

In some embodiments, the chalcogenide is a compound that includes at least one of sulfur (S), selenium (Se), or tellurium (Te).

In some embodiments, the first interface layer includes a first dielectric material that does not react with the chalcogenide and the first electrode.

In some embodiments, the methods further include fabricating a second interface layer on the chalcogenide switching layer, wherein the second electrode is fabricated on the second interface layer. The second interface layer includes a second dielectric material that does not react with the chalcogenide and the second electrode.

In some embodiments, the second interface layer and the first interface layer are of different thicknesses.

In some embodiments, the second interface layer and the first interface layer include different materials.

In some embodiments, the first electrode and the second electrode compromise at least one of tungsten, molybdenum, ruthenium, titanium nitride, tantalum nitride, tungsten nitride, platinum, palladium, or iridium.

According to one or more aspects of the present disclosure, a crossbar circuit is provided. The crossbar circuit includes a plurality of bit lines, a plurality of word lines, and a plurality of memory devices. Each of the memory devices is connected to one of the bit lines and one of the word lines. Each of the plurality of memory devices is configured to function as a switch and a memory cell.

In some embodiments, at least one of the memory devices includes a first electrode, a first interface layer fabricated on the first electrode, a chalcogenide switching layer fabricated on the first interface layer, wherein the chalcogenide switching layer includes at least one chalcogenide, wherein the first interface layer includes a first dielectric material that does not react with the chalcogenide; and a first electrode.

In some embodiments, the chalcogenide is a compound that includes at least one of sulfur (S), selenium (Se), or tellurium (Te).

In some embodiments, the at least one of the memory devices further includes a second interface layer positioned between the chalcogenide switching layer and the second electrode. The second interface layer includes a second dielectric material that does not react with the chalcogenide and the second electrode.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some embodiments of the present disclosure.

FIGS. 2A and 2B depict I-V characteristics of an example OTS memory device in accordance with some embodiments of the present disclosure.

FIGS. 3A, 3B, 3C, 3D, and 3E illustrate cross-sectional views of structures for fabricating an OTS memory device in accordance with some embodiments of the present disclosure.

FIGS. 4A, 4B, 4C, 4D, 4E, 5A, 5B, 5C, 5D, and 5E are schematic diagrams illustrating cross-sectional views of example structures of OTS memory devices in accordance with some embodiments of the present disclosure.

FIG. 6 is a flow diagram illustrating an example of a process for fabricating an OTS memory device according to some embodiments of the disclosure.

### DETAILED DESCRIPTION

Aspects of the disclosure provide memory devices utilizing Ovonic threshold switching (OTS) materials and crossbar circuits of the memory devices. OTS switching refers to a phenomenon where a material transitions from an insulating state to a conductive state when a specific threshold voltage is applied. Materials that exhibit OTS switching characteristics include chalcogenides, which are compounds containing at least one chalcogen element (such as sulfur (S), selenium (Se), tellurium (Te), etc.) combined with more electropositive elements, such as SiGeAsSe, GeSe, GeSbTe, and AgInSbTe. OTS is an electron-dominated switching process, which requires minimal ionic defects in the amorphous material. OTS chalcogenides may need to maintain amorphous states to ensure a very low leakage current.

OTS devices have traditionally been used as switches or selectors utilizing their high on/off current ratio. For example, when a voltage exceeding the threshold voltage (V_{TH}) is applied, the device changes from a low conductance (Off) state to a high conductance state (On) state. When the applied voltage is removed, the device returns to the low conductance (Off) state. The OTS switching is volatile. An OTS device may be used as a selector in a 1S1R configuration in a crossbar array, with S as the selector for the volatile switching, and R as the memristor for the non-volatile switching.

According to one or more aspects of the present disclosure, an OTS memory device may be used as a selector and a memory device in a similar 1S1R configuration in a crossbar array, with the new S performing as a selector and a memristor. The OTS memory device is a selector as well as a memristor, using the migration effect of ionic defects in the chalcogenide under switching polarities to store information (referred to as the OTS-memory effect). This effect may be enhanced by the interface layers applied in the OTS memory devices as described herein. The ability of OTS memory devices to function as both selectors and memristors allows for a more compact 1-memristor (1R) design in crossbar arrays. This may eliminate the need for a separate selector element, leading to higher memory density and lower fabrication and operation costs.

In some embodiments, a crossbar circuit may include word lines, bit lines, and a plurality of memory devices connecting to the word lines and bit lines. Each of the memory devices may be a two-terminal device that can function both as a selector and a memory cell. In some embodiments, each of the memory devices may include a first electrode, a second electrode, and a chalcogenide switching layer positioned between the first electrode and the second electrode. The chalcogenide switching layer may include one or more chalcogenides, such as SiGeAsSe, GeSe, GeSbTe, AgInSbTe, etc. The memory device may further include one or more interface layers positioned between the chalcogenide switching layer and the electrodes. Each of the interface layers may include a dielectric material that is more chemically stable than the chalcogenides in the chalcogenide switching layer and the electrode materials in the first electrode and/or the second electrode. Examples of the dielectric material may include Al₂O₃, Y₂O₃, or MgO. In some embodiments, the memory device may include a first interface layer positioned between the first electrode and the chalcogenide switching layer and a second interface layer positioned between the chalcogenide switching layer and the second electrode. The interface layers may act as a barrier layer that can prevent OTS/electrode interactions such as chemical reactions and diffusion that can deteriorate the performance of the memory device and can also preserve the accumulated ionic species (such as anion vacancies) at the interfaces that may cause the memory effect. In some embodiments, one or more of the interface layers may include a discontinuous film of a dielectric material, which can reduce the contact area between the chalcogenide and the electrodes and further enhance the retention of the memory device.

In one implementation, the memory device may include symmetric interface layers that have the same dielectric materials and the same thickness. In another implementation, the memory device may include asymmetric interface layers (e.g., interface layers having different thicknesses and/or materials). The asymmetric interface layers may further enhance the OTS-only memory signal by enhancing the difference in the accumulation of ionic species at interfaces and by enhancing the polarity effect on the accumulation of ionic species at interfaces.

The memory devices described herein may exhibit different I-V characteristics in response to varying voltages, allowing them to store information corresponding to multiple memory states and function as both switches and memory cells. Unlike conventional crossbar circuits that use transistors for access control to memory cells (e.g., memristors), the crossbar circuits described herein do not require transistors for access control, enabling low-cost, high-density crossbar arrays.

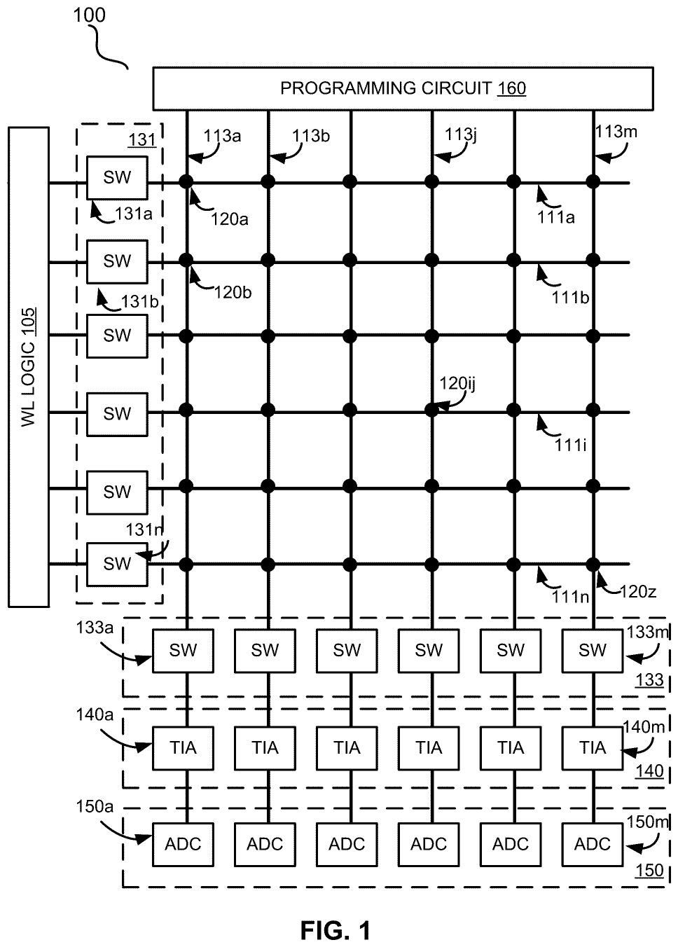

FIG. 1 is a diagram illustrating an example 100 of a crossbar circuit in accordance with some embodiments of the present disclosure. As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120z, etc. Each of the cross-point devices may connect a row wire and a column wire. For example, the cross-point device 120ij may connect the row wire 111i and the column wire 113j. The number of the column wires 113a-m and the number of the row wires 111a-n may or may not be the same. Crossbar circuit 100 may further include a word line (WL) logic 105 that is connected to the cross-point devices via the row wires 111a-111n. The WL logic 105 may include any suitable component for applying input signals to selected cross-point devices via row wires 111a-111n, such as one or more digital-to-analog converters (DACs), amplifiers, etc. Each of the input signals may be a voltage signal, a current signal, etc.

Row wires 111a-n may include a first row wire 111a, a second row wire 111b, . . . , 111i, . . . , and an n-th row wire 111n. Each of row wires 111a, . . . , 111n may be and/or include any suitable electrically conductive material. In some embodiments, each row wire 111a-111n may be a metal wire. In some embodiments, each row wire 111a-111n may be a word line.

Column wires 113a-m may include a first column wire 113a, a second column wire 113b, . . . , and an m-th column wire 113m. Each column wire 113a-m may be and/or include any suitable electrically conductive material. In some embodiments, each column wire 113a-m may be a metal wire. In some embodiments, each column wire 113a-m may be a bit line.

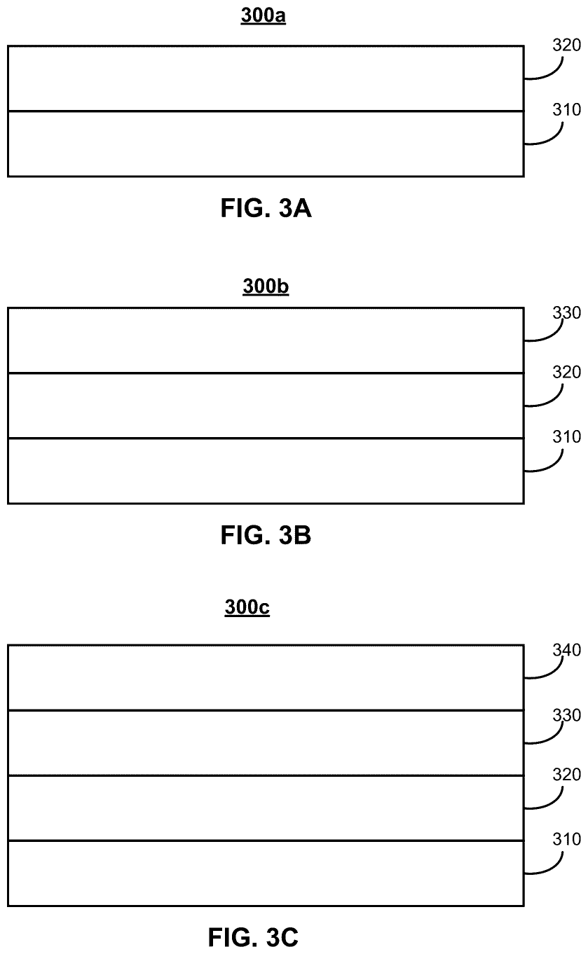

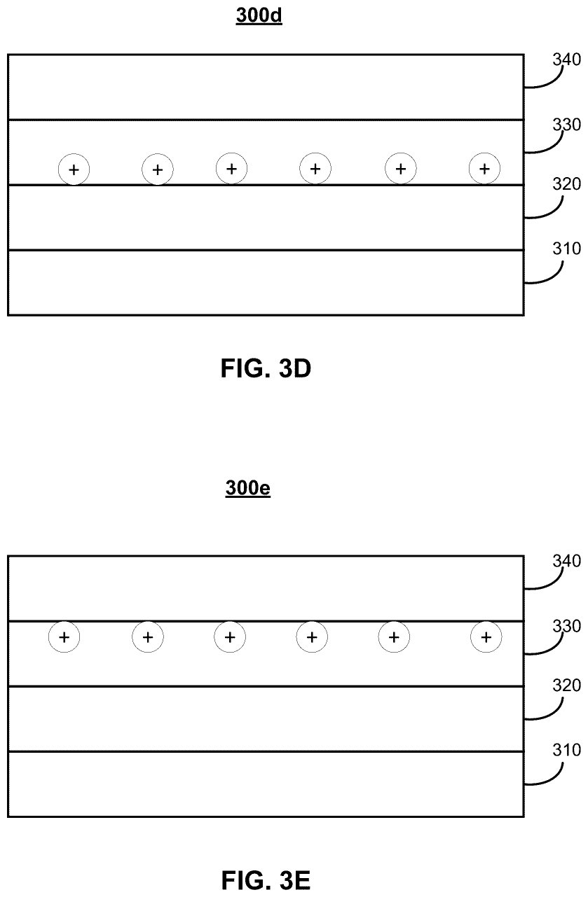

Each cross-point device 120a-120z may be and/or include a two-terminal device that is configured to function as both a selector and a memory cell. Each cross-point device 120a-z may include two electrodes and a chalcogenide switching layer fabricated between the two electrodes. The chalcogenide switching layer may include a chalcogenide, such as SiGeAsSe, GeSe, GeSbTe, AgInSbTe, etc. Cross-point devices 120a-120z may include an OTS memory device as described in connection with FIGS. 3A-5.

Each row wire 111a-n may be connected to one or more row switches 131 (e.g., row switches 131a, 131b, . . . 131n). Each row switch 131 may include any suitable circuit structure that may control the input voltage through row wires 111a-n. For example, row switches 131 may be and/or include a CMOS switch circuit.

Each column wire 113a-m may be connected to one or more column switches 133 (e.g., switches 133a, . . . , 133m). Each column switch 133a-m may include any suitable circuit structure that may control current passing through column wires 113a-m. For example, column switches 133a-m may be and/or include a CMOS switch circuit. In some embodiments, one or more of switches 131a-n and 133a-m may further provide fault protection, electrostatic discharge (ESD) protection, noise reduction, and/or any other suitable function for one or more portions of crossbar circuit 100.

Output sensor(s) 140 may include any suitable component for converting the current flowing through column wires 113a-n into the output signal, such as one or more TIAs (trans-impedance amplifier) 140a, . . . , 140m. Each TIA 140a-m may convert the current flowing through a respective column wire into a respective voltage signal. Each ADC 150 (e.g., ADC 150a, . . . , 150m) may convert the voltage signal produced by its corresponding TIA into a digital output. In some embodiments, output sensor(s) 140 may further include one or more multiplexers (not shown).

Programming circuit 160 may program the cross-point devices 120a-z selected by switches 131 and/or 133 to suitable conductance values and/or memory states. For example, programming a memory device 120a-120z to a first memory state (e.g., a state “1”) may involve applying a write voltage having a first polarity (e.g., a positive voltage) to the memory device. The application of the first write voltage may migrate the ionic defects towards one of the electrodes (for example, the first electrode), thereby storing a “1.” A write operation to program the memory device to a second memory state (e.g., a “0” state) may involve applying a second write voltage of a second polarity (e.g., a negative voltage) to the memory device by migrating the ionic defects towards the opposite electrode (for example, the second electrode). The application of the second write voltage may reverse the change induced by the first voltage by migrating the ionic defects to the opposite electrode, thereby storing a “0”.

WL logic 105 may perform read operations on the programmed memory devices. Performing a read operation on a memory device 120a-120z may involve applying a read voltage to the memory device. In some embodiments, the read voltage may be a positive voltage. If the memory device has been written to the first state by a previous positive voltage before the read operation, the application of the positive read voltage to the memory device may not change the ionic migration in the device, causing the memory state to remain in the first state, and the threshold voltage will remain unchanged. If the memory device has been written to the second memory state by a negative voltage previously applied to the memory device before the read operation, the application of the positive read voltage to the memory device will cause ionic migration towards the opposite electrode, and the threshold voltage will be slightly higher due to the extra work of migrating the ionic defects to the opposite electrode. The difference in threshold voltages may be used to distinguish the previous write polarities, which may be used as a memory to store information. After the read operation, the memory state is considered changed by the reading process itself. A negative pulse is subsequently applied to restore the device to its original “0” state.

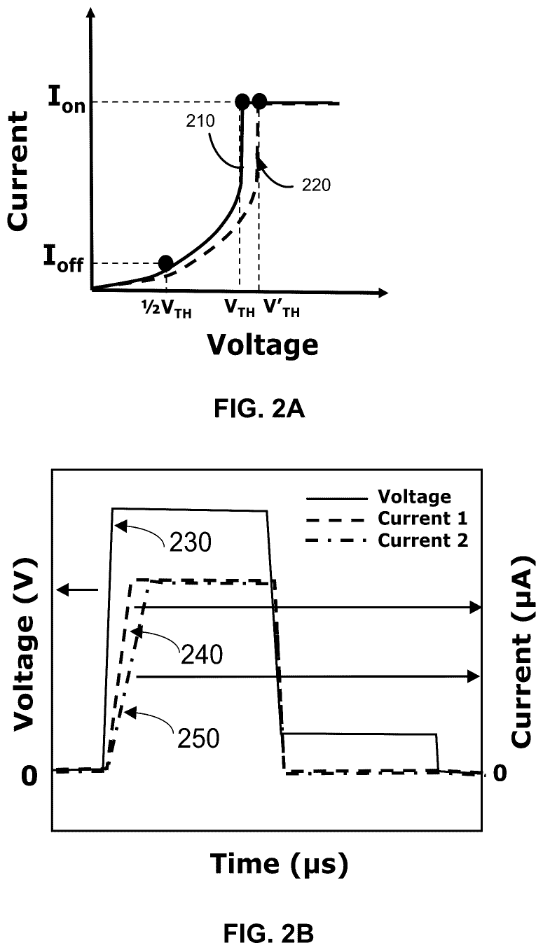

FIGS. 2A and 2B depict I-V characteristics of an example OTS memory device during read operations in accordance with some embodiments of the present disclosure.

FIG. 2A shows current-voltage (I-V) curves that depict I-V characteristics of the OTS memory device at different memory states. I-V curve 210 represents the I-V characteristics when the OTS memory device is at a first memory state (e.g., state “1”). I-V curve 210 shows a threshold voltage V_{TH}, corresponding to the threshold voltage required to switch the OTS memory device from an “off” state to an “on” state. The current corresponding to V_{TH} is referred to as Iₒₙ. The current corresponding to half of the threshold voltage (½V_{TH}) is referred to as I_{off}. The current I_{off} should be sufficiently low to prevent interaction with adjacent cells. The selector ratio, defined as Iₒₙ/I_{off}, must be sufficiently high (e.g., greater than 10⁴). OTS is an electron-dominated switching process, which requires minimal ionic defects in the amorphous material. OTS chalcogenides should maintain an amorphous state to ensure a very low leakage current (I_{off} at ½V_{TH}).

I-V curve 220 represents the I-V characteristics when the OTS memory device is at a second memory state (e.g., a state “0”). I-V curve 220 includes a threshold voltage V′_{TH}, which is slightly higher than V_{TH}, and may indicate a different memory state before the read operation. A positive pulse may be applied to the OTS memory device to write the state “1” to the memory device. A negative pulse may be applied to the OTS memory device to write the state “0” to the OTS memory device. The values of V′_{TH} and V_{TH} should be sufficiently distinguishable so that the OTS memory device may operate at two distinctive memory states. The interface layers described herein may enhance the difference between the values of V′_{TH} and V_{TH}, which may thus enable OTS memory devices to store information with the two distinct memory states.

Referring to FIG. 2B, I-V curve 230 depicts a voltage pulse applied to the OTS memory device over time. I-V curve 240 depicts the current response of the OTS memory device at the first memory state (e.g., state “1”). I-V curve 250 depicts the current response of the OTS memory device at the second memory state (e.g., state “0”). If the memory device has been written to state “1” and a positive read voltage is applied to the memory device, the memory device may remain at state “1” and may be refreshed by the application of the positive read voltage.

If the memory device has been written to state “0” and a positive read voltage is applied to the memory device, the I-V characteristics of the memory device may be represented by curve 250. The memory state of the memory device is thus changed by the reading voltage. A negative voltage may be applied to the memory device subsequently to write the memory device back to state “0.”

FIGS. 3A, 3B, 3C, 3D, and 3E illustrate cross-sectional views of structures 300a, 300b, 300c, and 300d for fabricating an OTS memory device in accordance with some embodiments of the present disclosure.

As shown in FIG. 3A, a substrate 310 may be provided. A first electrode 320 may be fabricated on the substrate 310. Substrate 310 may include one or more layers of any suitable material that may serve as a substrate for an OTS memory device, such as silicon (Si), silicon dioxide (SiO₂), silicon nitride (Si₃N₄), aluminum oxide (Al₂O₃), aluminum nitride (AlN), etc. In some embodiments, the substrate 310 may include diodes, transistors, interconnects, integrated circuits, one or more other OTS memory devices, etc. In some embodiments, substrate 310 may include a driving circuit including one or more electrical circuits (e.g., an array of electrical circuits) that may be individually controllable. In some embodiments, the driving circuit may include one or more complementary metal-oxide-semiconductor (CMOS) drivers.

The first electrode 320 may include any suitable material that is electronically conductive and non-reactive to the chalcogenide switching layer to be fabricated on the first electrode 320. As an example, the first electrode 320 may include a non-reactive metal, such as tungsten (W), ruthenium (Ru), molybdenum (Mo), etc. As another example, the first electrode 320 may include a metal nitride with suitable chemical stability so that it will not react with chalcogenide anions during OTS memory switching, such as titanium nitride (TiN), tantalum nitride (TaN), etc.

Referring to FIG. 3B, a chalcogenide switching layer 330 may be fabricated on the first electrode 320. The chalcogenide switching layer 330 may include one or more chalcogenides. A chalcogenide may be a compound including at least one chalcogen element (such as sulfur (S), selenium (Se), tellurium (Te), etc.) combined with more electropositive elements, such as SiGeAsSe, GeSe, GeSbTe, AgInSbTe, etc.

As shown in FIG. 3C, a second electrode 340 may be fabricated on the chalcogenide switching layer 330 to fabricate an OTS memory device 300c. The second electrode 340 may include any suitable electrically conductive material, such as metals (e.g., W, Ru, Mo, etc.) and/or nitrides (e.g., TiN, TaN, WN, etc.). The second electrode 340 and the first electrode 320 may or may not contain the same material.

The OTS memory device operates through an electron-dominated switching process, with the potential presence of minor structural defects in the amorphous chalcogenide phase, such as arsenic (As) anions and selenium (Se) anions. These anions may migrate through the chalcogenide switching layer 330 via a vacancy mechanism, and these anion vacancies can be viewed as positively charged ionic species. Upon the application of a first positive voltage pulse on the second electrode 340, As and/or Se vacancies may be driven towards the first electrode 320 side, as illustrated in FIG. 3D. The I-V characteristics of the memory device after the application of the first positive voltage (also referred to as the first I-V characteristics) may be represented as I-V curve 210 of FIG. 2A. If a second positive voltage pulse is subsequently applied to the second electrode 340, the As and/or Se vacancies remain located at the first electrode side, resulting in the second I-V characteristics of the memory device after the application of the second positive voltage being similar to the first OTS I-V characteristics. Conversely, if a second negative voltage pulse is subsequently applied to the second electrode 340 after the application of the first positive voltage, the As and/or Se vacancies may be driven from the first electrode 320 side back towards the second electrode 340 side, as shown in FIG. 3E, causing the second I-V characteristics to differ from the first I-V characteristics due to the additional work required to drift the As and/or Se vacancies to the opposite side. The origin of the OTS-only memory effect may be attributed to differences in the second OTS I-V characteristic compared to the first OTS I-V characteristic when the two voltage pulses have opposite polarities. The second OTS switching event can drive the accumulated ionic species from one electrode to the other. When the second pulse has a different polarity than the first, the second OTS exhibits a higher threshold voltage due to the additional work required for the second pulse to move the accumulated ionic species from one electrode interface to the other electrode interface. The diffusion of the accumulated ionic species away from the interface can lead to the loss of the OTS-only memory effect, also known as retention loss.

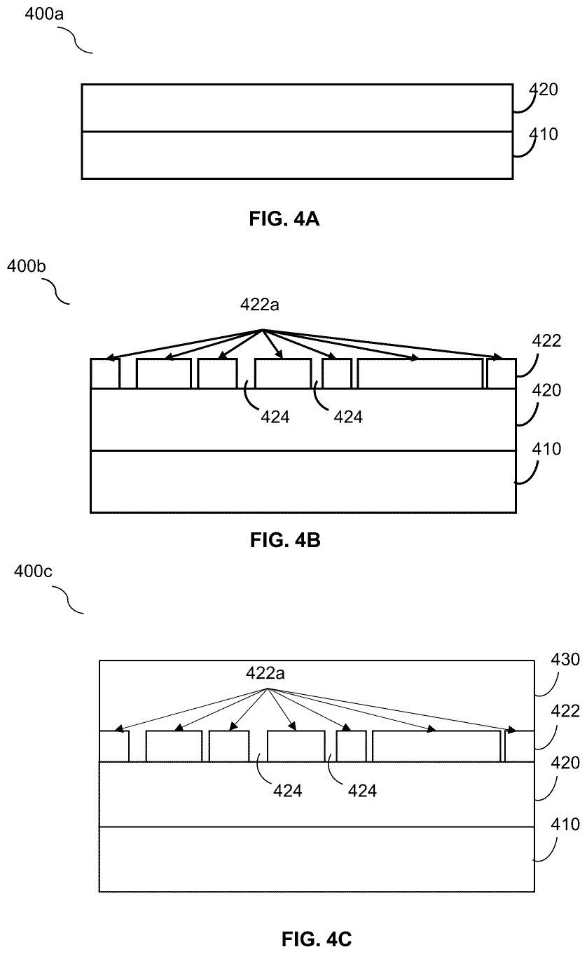

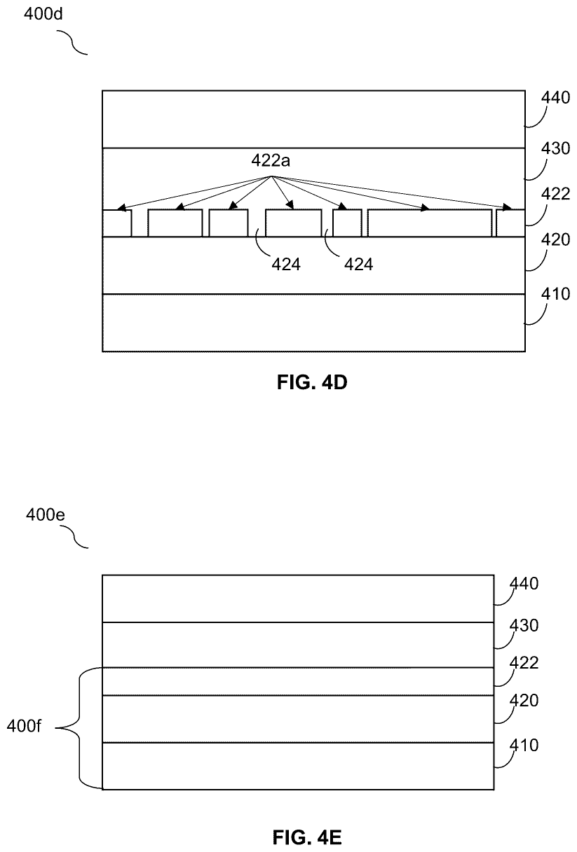

FIGS. 4A, 4B, 4C, 4D, and 4E are schematic diagrams illustrating cross-sectional views of example structures 400a, 400b, 400c, 400d, and 400e of OTS memory devices in accordance with some embodiments of the present disclosure.

As illustrated in FIG. 4A, a first electrode 420 may be fabricated on a substrate 410. The first electrode 420 and the substrate 410 may correspond to the first electrode 320 and the substrate 310 as described in conjunction with FIG. 3A, respectively.

As illustrated in FIG. 4B, an interface layer 422 (also referred to as the “first interface layer”) may be fabricated on the first electrode 420. The interface layer 422 may a first dielectric material that is more chemically stable than the chalcogenide(s) in the chalcogenide switching layer to be fabricated on the interface layer 422 and the electrode materials in the electrodes of the OTS memory device to be fabricated. As a result, the dielectric material will not react with the chalcogenide(s) in the chalcogenide switching layer or the electrode materials. Examples of the first dielectric material include A1₂O₃, Y₂O₃, MgO, etc.

As shown, the discontinuous film 422a may include pores and/or pin-holes 424 that are randomly dispersed in the interface layer 422. While a certain number of pores are illustrated in FIG. 4B, this is merely illustrative. The discontinuous film 422a may include any suitable number of pores and/or pin-holes. In some embodiments, a thickness of the interface layer 422 and/or the discontinuous film 422a may be between about 0.2 nm and about 0.5 nm. In some embodiments, the discontinuous film 422a may be an Al₂O₃ film having a thickness equal to or less than 0.5 nm. In some embodiments, the discontinuous film 422a may be and/or include an Al₂O₃ film having a thickness of less than 1 nm.

As illustrated in FIG. 4C, a chalcogenide switching layer 430 may be fabricated on the interface layer 422. The chalcogenide switching layer 430 may include one or more chalcogenides, such as SiGeAsSe, GeSe, GeSbTe, AgInSbTe, etc.

In some embodiments in which the interface layer 422 includes a discontinuous film of the first dielectric material, during the fabrication of the chalcogenide switching layer 430, one or more portions of the chalcogenides may be disposed on the first electrode 420 through one or more pores/pin-holes 424. As such, the chalcogenide switching layer 430 may directly contact one or more portions of the first electrode 420.

As shown in FIG. 4D, a second electrode 440 may be fabricated on the chalcogenide switching layer 430, as an example of a device with asymmetric interfaces. In some embodiments, the second electrode 440 may include the second electrode 340 as described in connection with FIGS. 3C-3D.

The interface layer in OTS devices primarily acts as a barrier layer that prevents deleterious OTS/electrode interactions, such as chemical reactions and diffusion, which could deteriorate the performance of OTS devices. Additionally, this layer preserves accumulated ionic species, such as anions or anion vacancies, at the interfaces, enhancing memory retention. Moreover, the interface layer can affect the degree of contact between the chalcogenide and electrodes, which is critical for device functionality, especially since these layers can be non-continuous. This configuration is essential for maintaining the integrity and performance of OTS devices under varying operational conditions.

In some embodiments, as shown in FIG. 4E, interface layer 422 may include a continuous layer of the first dielectric material. Substrate 410, first electrode 420, and chalcogenide switching layer 430 are also collectively referred to herein as structure 400f.

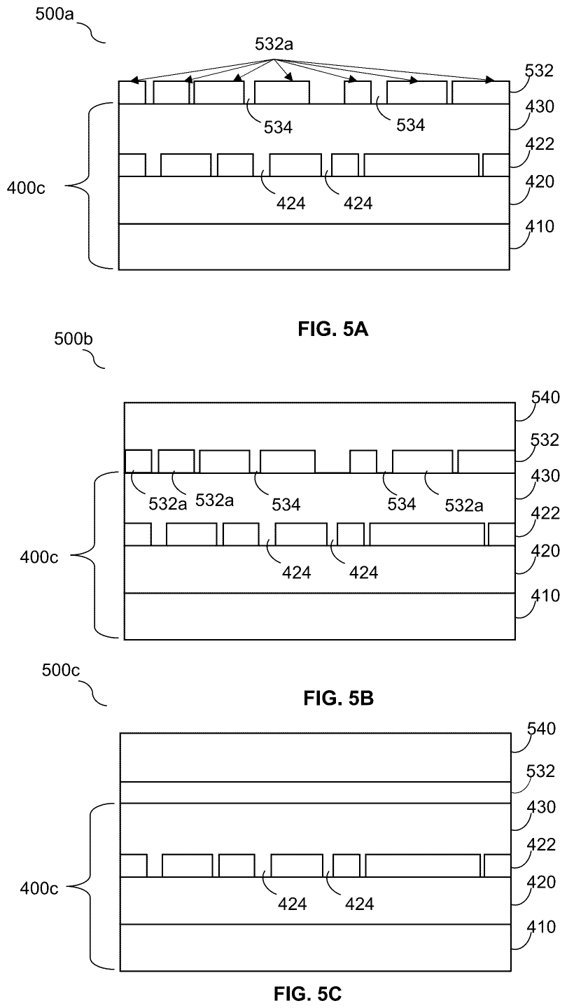

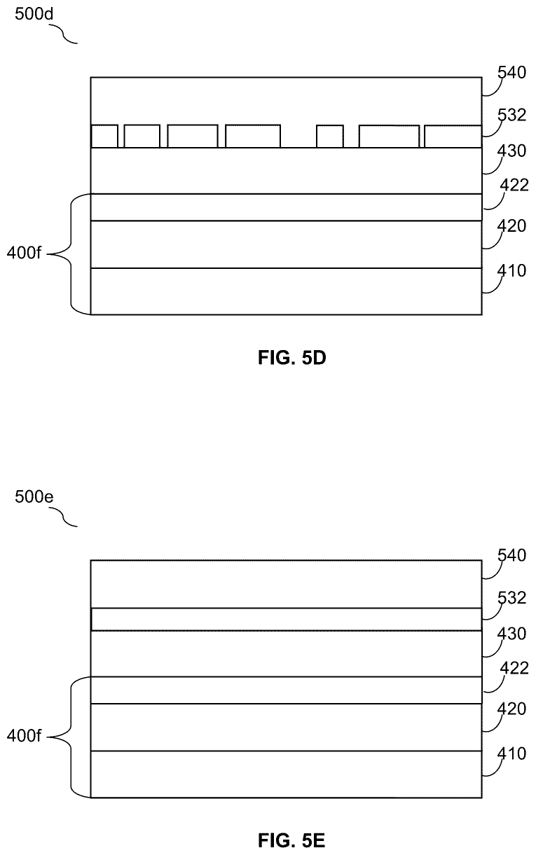

In some embodiments, an OTS memory device may include multiple interface layers fabricated between the first electrode and the second electrode. For example, as illustrated in FIG. 5A, a semiconductor device 500a may be fabricated by fabricating an interface layer 532 (also referred to as the “second interface layer”) on the structure 400c as described in connection with FIG. 4C. In some embodiments, the second interface layer 532 may include a discontinuous film 532a of a second dielectric material. The second dielectric material may be more chemically stable than the chalcogenide in chalcogenide switching layer 430. As an example, the second dielectric material may include Al₂O₃, MgO, Y₂O₃, etc. The second dielectric material may or may not be the same as the first dielectric material.

The discontinuous film 532a may include one or more pores and/or pin-holes 534 (also referred to as the “one or more second pores and/or pin-holes”). The pore(s) 534 may have any suitable size and/or dimension. Multiple pores 534 may or may not have the same size and/or dimension. In some embodiments, the second interface layer 532 and/or the second discontinuous film 532a may include multiple pores 534 dispersed randomly on the second interface layer 532. The discontinuous film 532a may include any suitable number of pores and/or pin-holes.

In some embodiments, a thickness of the second interface layer 532 and/or the second discontinuous film (also referred to as the “second thickness”) may be between about 0.2 nm and about 0.5 nm. As another example, the second interface layer 532 may include a discontinuous Al₂O₃ film having a thickness equal to or less than 0.5 nm. In some embodiments, the second interface layer 532 may include a discontinuous Al₂O₃ film having a thickness less than 1 nm. The second thickness of the second interface layer 532 may or may not be the same as the first thickness of the first interface layer 422.

As illustrated in FIG. 5B, a second electrode 540 may be fabricated on the second interface layer 532 to fabricate an OTS memory device 500b. The second interface layer 532 is positioned between the chalcogenide switching layer 430 and the second electrode 540. The second electrode 540 may be and/or include the second electrode 340 as described in conjunction with FIGS. 3C-3D. In some embodiments, during the fabrication of the second electrode 540, one or more portions of the second electrode 540 may be disposed on the chalcogenide switching layer 430 through one or more pores and/or pin-holes 534. That is, at least some of the Ru in the second electrode 540 is deposited on the chalcogenide switching layer 430 through pores and/or pin-holes 534. As such, the second electrode 540 may directly contact one or more portions of the chalcogenide switching layer 430 through one or more pores/pin-holes 534.

In one implementation, interface layers 422 and 532 may include the same material, such as Al₂O₃, MgO, Y₂O₃, etc., and may have the same thickness (e.g., 2 nm, 3 nm, 4 nm, 5 nm, etc.). In another implementation, interface layers 422 and 532 may include different materials and/or may have different thicknesses to enhance the OTS-only memory signals, to improve memory retention by preserving the accumulation of ionic species at interfaces, and to enhance the difference in ion accumulation under different switching polarities. For example, one interface layer may be 2 nm thick while the other interface layer may be 4 nm thick, or one interface layer may be 3 nm thick, and the other interface layer may be 5 nm thick. As another example, interface layers 422 and 532 may include different materials, such as any two of Al₂O₃, Y₂O₃, MgO, etc., with possible combinations like Al₂O₃ and Y₂O₃, or Al₂O₃ and MgO, while maintaining the same thicknesses, such as 2 nm, 3 nm, 4 nm, 5 nm, etc. The interface layers may also feature different materials with different film thicknesses.

As shown in FIG. 5C, second interface layer 532 may be a continuous layer of the second dielectric material in some embodiments. As shown in FIG. 5D, second interface layer 532 may include a discontinuous layer of the second dielectric material, while interface layer 422 may include a continuous layer of the first dielectric material. In some embodiments, second interface layer 532 may be omitted from the OTS memory device. As shown in FIG. 5E, each of interface layers 422 and 532 may be a continuous layer.

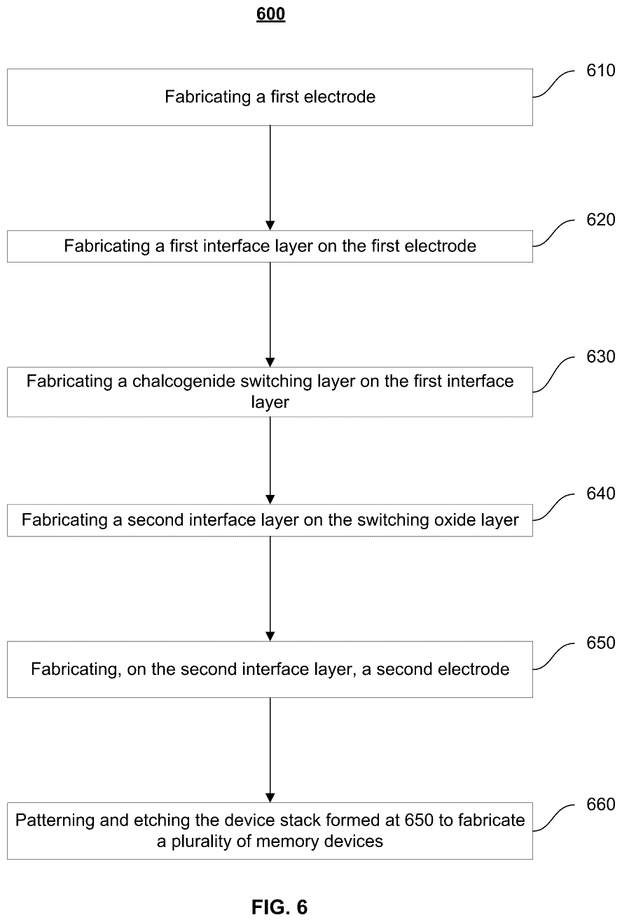

FIG. 6 is a flow diagram illustrating an example 600 of a process for fabricating an OTS memory device according to some embodiments of the disclosure.

At block 610, a first electrode may be fabricated on a substrate. For example, a layer of a suitable electrically conductive material may be deposited utilizing atomic layer deposition (ALD), chemical vapor deposition (CVD), metal-organic chemical vapor deposition (MOCVD), physical vapor deposition (PVD), molecular beam epitaxy (MBE) deposition, etc. The electrically conductive material may include, for example, W, Mo, Ru, TiN, TaN, WN, Pt, Pd, Ir, etc. In some embodiments, a thin layer of an adhesion material, such as Ti, Ta, etc., may be fabricated between the substrate and the first electrode.

At block 620, a first interface layer may be fabricated on the first electrode. The first interface layer may include a first dielectric material that is more chemically stable than the chalcogenide(s) of the chalcogenide switching layer described below and the electrode materials in the first electrode. For example, fabricating the first interface layer may involve depositing AlOₓ, utilizing an atomic layer deposition (ALD) technique, a physical vapor deposition (PVD) technique, a reactive sputtering of Al technique, and/or any other suitable deposition technique. The first interface layer may be and/or include the interface layer 422 as described in connection with FIGS. 4C-5D above.

At block 630, a chalcogenide switching layer comprising one or more chalcogenides may be fabricated on the first interface layer. For example, fabricating the chalcogenide switching layer may involve depositing one or more of SiGeAsSe, GeSe, GeSbTe, AgInSbTe, etc. utilizing an ALD technique, a PVD technique, and/or any other suitable deposition technique. The chalcogenide switching layer may be and/or include chalcogenide switching layer 430 as described in connection with FIGS. 4C-5D above. In some embodiments in which the first interface layer includes a discontinuous film of the first dielectric material, one or more portions of the chalcogenide switching layer may be deposited on the first electrode through the pin-holes in the first interface layer.

At block 640, a second interface layer may be fabricated on the chalcogenide switching layer. The second interface layer may include a second material that is more chemically stable than the chalcogenide(s) of the chalcogenide switching layer and the electrode materials in the first electrode and/or the second electrode, such as Al₂O₃, Y₂O₃, MgO, etc. For example, fabricating the second interface layer may involve depositing the second material, utilizing an ALD technique, a physical vapor deposition (PVD) technique, a reactive sputtering of Al technique, and/or any other suitable deposition technique. The first interface layer may be and/or include the interface layer 532 as described in connection with FIGS. 5A-5D above.

At block 650, a second electrode may be fabricated on the second interface layer. Fabricating the second electrode may involve fabricating one or more layers of a suitable electrically conductive material utilizing suitable deposition techniques, such as ALD, CVD, MOCVD, PVD, MBE, etc.

At block 660, the device stack formed at 650 may be patterned and etched to fabricate a plurality of memory devices. In some embodiments, block 630 or block 640 may be omitted from process 500 to form an OTS memory device with a single interface layer.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A memory device, comprising:
a first electrode;
a first interface layer fabricated on the first electrode;
a chalcogenide switching layer fabricated on the first interface layer, wherein the chalcogenide switching layer comprises at least one chalcogenide; and
a second electrode fabricated on the chalcogenide switching layer.

2. The memory device of claim 1, wherein the chalcogenide is a compound comprising at least one of sulfur (S), selenium (Se), or tellurium (Te).

3. The memory device of claim 1, wherein the first interface layer comprises a first dielectric material that does not react with the chalcogenide and the first electrode.

4. The memory device of claim 3, wherein the first dielectric material comprises at least one of Al₂O₃, Y₂O₃, or MgO.

5. The memory of claim 3, wherein the first interface layer comprises a discontinuous film of the first dielectric material, and wherein at least a portion of the chalcogenide switching layer is deposited on the first electrode.

6. The memory device of claim 3, further comprising a second interface layer positioned between the chalcogenide switching layer and the second electrode, wherein the second interface layer comprises a second dielectric material that does not react with the chalcogenide and the second electrode.

7. The memory device of claim 6, wherein the second interface layer and the first interface layer are of different thicknesses.

8. The memory device of claim 6, wherein the second interface layer and the first interface layer comprise different materials.

9. The memory device of claim 1, wherein the first electrode and the second electrode compromise at least one of tungsten, molybdenum, ruthenium, titanium nitride, tantalum nitride, tungsten nitride, platinum, palladium, or iridium.

10. A method for fabricating a memory device, comprising:
fabricating a first electrode;
fabricating a first interface layer fabricated on the first electrode;
fabricating a chalcogenide switching layer fabricated on the first interface layer, wherein the chalcogenide switching layer comprises at least one chalcogenide; and
fabricating a second electrode on the chalcogenide switching layer.

11. The method of claim 10, wherein the chalcogenide is a compound comprising at least one of sulfur (S), selenium (Se), or tellurium (Te).

12. The method of claim 10, wherein the first interface layer comprises a first dielectric material that does not react with the chalcogenide and the first electrode.

13. The method of claim 10, further comprising fabricating a second interface layer on the chalcogenide switching layer, wherein the second electrode is fabricated on the second interface layer, and wherein the second interface layer comprises a second dielectric material that does not react with the chalcogenide and the second electrode.

14. The method of claim 13, wherein the second interface layer and the first interface layer are of different thicknesses.

15. The method of claim 13, wherein the second interface layer and the first interface layer comprise different materials.

16. The method of claim 10, wherein the first electrode and the second electrode compromise at least one of tungsten, molybdenum, ruthenium, titanium nitride, tantalum nitride, tungsten nitride, platinum, palladium, or iridium.

17. A crossbar circuit, comprising:
a plurality of bit lines;
a plurality of word lines; and
a plurality of memory devices, wherein each of the memory devices is connected to one of the bit lines and one of the word lines, wherein each of the plurality of memory devices is configured to function as a switch and a memory cell.

18. The crossbar circuit of claim 17, wherein at least one of the memory devices comprises:
a first electrode;
a first interface layer fabricated on the first electrode;
a chalcogenide switching layer fabricated on the first interface layer, wherein the chalcogenide switching layer comprises at least one chalcogenide, wherein the first interface layer comprises a first dielectric material that does not react with the chalcogenide; and
a second electrode.

19. The crossbar circuit of claim 18, wherein the chalcogenide is a compound comprising at least one of sulfur (S), selenium (Se), or tellurium (Te).

20. The crossbar circuit of claim 19, wherein the at least one of the memory devices further comprises a second interface layer positioned between the chalcogenide switching layer and the second electrode, wherein the second interface layer comprises a second dielectric material that does not react with the chalcogenide and the second electrode.
